(19) United States
(12) Patent Application Publication
(10) Pub. No.: US 2010/0159632 A1
(43) Pub. Date: Jun. 24, 2010

(54) TECHNIQUE FOR FABRICATION OF BACKSIDE ILLUMINATED IMAGE SENSOR

(75) Inventors: Howard E. Rhodes, San Martin, CA (US); Hsin-Chih Tai, Cupertino, CA (US)

Correspondence Address: BLAKELY SOKOLOFF TAYLOR & ZAFMAN LLP, 1279 Oakmead Parkway, Sunnyvale, CA, 94085-4040, US

(73) Assignee: OmniVision Technologies, Inc., Santa Clara, CA (US)

(21) Appl. No.: 12/342,973

(22) Filed: Dec. 23, 2008

(51) Int. Cl. H01L 21/02

(52) U.S. Cl. 438/73; 438/57; 257/E23.001

(57) ABSTRACT

An array of backside illuminated image sensors is fabricated using a number of processes. These processes include fabricating front side components of the backside illuminated image sensors into or onto a first side of an epitaxial layer disposed over a substrate layer. Dopants are diffused from the substrate through a second side of the epitaxial layer to create a dopant gradient band in the epitaxial layer adjacent to the substrate layer. The backside of the array is then thinned to remove the substrate layer while retaining at least a portion of the dopant gradient band in the epitaxial layer.

### TECHNICAL FIELD

This disclosure relates generally to image sensors, and in particular but not exclusively, relates to backside illuminated CMOS image sensors.

### BACKGROUND INFORMATION

FIG. 1 illustrates a backside illuminated (“BSI”) image sensor 100 including a photodiode (“PD”) region 105 disposed within a silicon epitaxial (“epi”) layer 110. Pixel circuitry for operation of the BSI image sensor is formed over a P well 115. Only the transfer transistor and the reset transistor of the pixel circuitry are illustrated. A first metal layer M1 for coupling to the gates of the transfer and reset transistors is disposed within an inter-metal dielectric layer 120.

BSI image sensor 100 is photosensitive to light incident upon the backside of the sensor die. For BSI image sensors, the majority of photon absorption occurs near the backside silicon surface. To separate the electron-hole pairs created by photon absorption and drive the electrons to PD region 105, an electric field near the back silicon surface is helpful. This electric field may be created by implanting dopants along the back surface and laser annealing.

Laser annealing is an annealing process which creates localized heating. The laser pulse can raise the back surface temperature greatly (e.g., in excess of 1000 C), but due to the short pulse, the temperature typically reduces quickly in the bulk of the silicon. However, when the silicon is thin, the insulation from inter-metal dielectric layer 120 and the remainder of the back-end-of-the-line (“BEOL”) may cause a significant increase in substrate temperature that can result in deleterious effects, such as dopant diffusion within the frontside pixel circuitry at temperatures greater than 800 C and/or BEOL metal deterioration/melting at temperatures greater than 400 C. Additional difficulties with this approach include 1) manufacturability issues associated with the added backside doping process, 2) backside defects caused by the laser anneal, 3) high dark current, and 4) high white pixel count.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIG. 1 is a cross sectional view of a backside illuminated image sensor.

FIG. 2 is a block diagram illustrating a backside illuminated imaging system, in accordance with an embodiment of the invention.

FIG. 3 is a circuit diagram illustrating pixel circuitry of two 4T pixels within a backside illuminated imaging system, in accordance with an embodiment of the invention.

FIG. 4 is a cross sectional view of backside illuminated image sensor, in accordance with an embodiment of the invention.

FIG. 5 is a flow chart illustrating a process for fabricating a backside illuminated image sensor, in accordance with an embodiment of the invention.

FIG. 6A is a cross sectional view of a partially fabricated backside illuminated image sensor fabricated up to completion of the BEOL, in accordance with an embodiment of the invention.

FIG. 6B is a cross sectional view of a partially fabricated backside illuminated image sensor illustrating diffusion of substrate dopants into the epi layer, in accordance with an embodiment of the invention.

FIG. 6C is a cross sectional view of a partially fabricated backside illuminated image sensor illustrating bonding of a handling wafer, in accordance with an embodiment of the invention.

FIG. 6D is a cross sectional view of a partially fabricated backside illuminated image sensor illustrating removal of the substrate, in accordance with an embodiment of the invention.

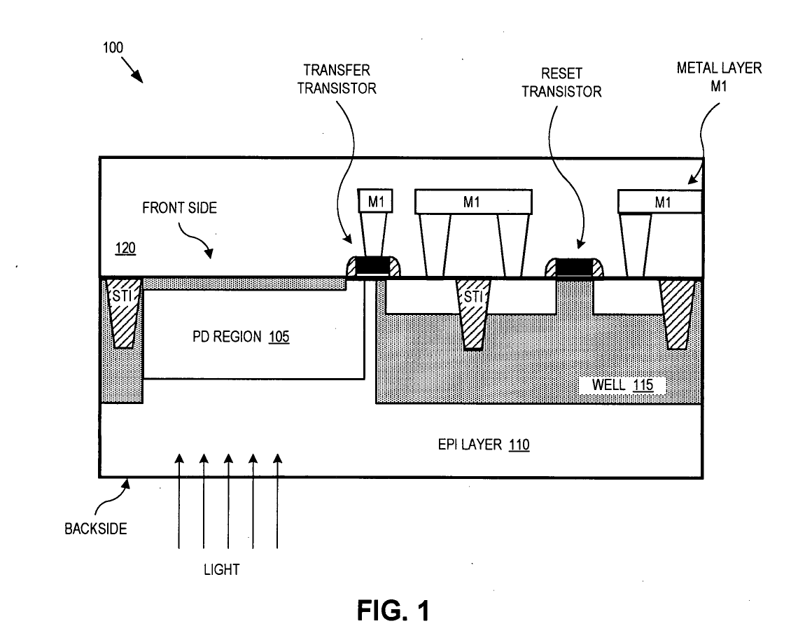

### DETAILED DESCRIPTION

Embodiments of a system and method for fabricating a backside illuminated (“BSI”) imaging sensor are described herein. In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

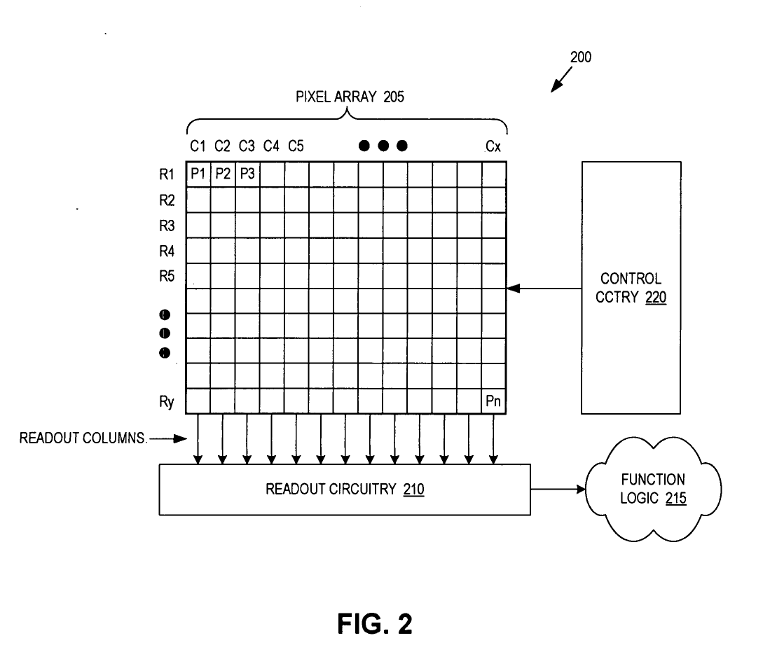

FIG. 2 is a block diagram illustrating a BSI imaging system 200, in accordance with an embodiment of the invention. The illustrated embodiment of imaging system 200 includes a pixel array 205, readout circuitry 210, function logic 215, and control circuitry 220.

Pixel array 205 is a two-dimensional (“2D”) array of backside illuminated imaging sensors or pixels (e.g., pixels P1, P2 . . . , Pn). In one embodiment, each pixel is a complementary metal-oxide-semiconductor (“CMOS”) imaging pixel. As illustrated, each pixel is arranged into a row (e.g., rows RI to Ry) and a column (e.g., column C1 to Cx) to acquire image data of a person, place, or object, which can then be used to render a 2D image of the person, place, or object.

After each pixel has acquired its image data or image charge, the image data is readout by readout circuitry 210 and transferred to function logic 215. Readout circuitry 210 may include amplification circuitry, analog-to-digital (“ADC”) conversion circuitry, or otherwise. Function logic 215 may simply store the image data or even manipulate the image data by applying post image effects (e.g., crop, rotate, remove red eye, adjust brightness, adjust contrast, or otherwise). In one embodiment, readout circuitry 210 may readout a row of image data at a time along readout column lines (illustrated) or may readout the image data using a variety of other techniques (not illustrated), such as a serial readout or a full parallel readout of all pixels simultaneously.

Control circuitry 220 is coupled to pixel array 205 to control operational characteristics of pixel array 205. For example, control circuitry 220 may generate a shutter signal for controlling image acquisition. In one embodiment, the shutter signal is a global shutter signal for simultaneously enabling all pixels within pixel array 205 to simultaneously capture their respective image data during a single acquisition window. In an alternative embodiment, the shutter signal is a rolling shutter signal whereby each row, column, or group of pixels is sequentially enabled during consecutive acquisition windows.

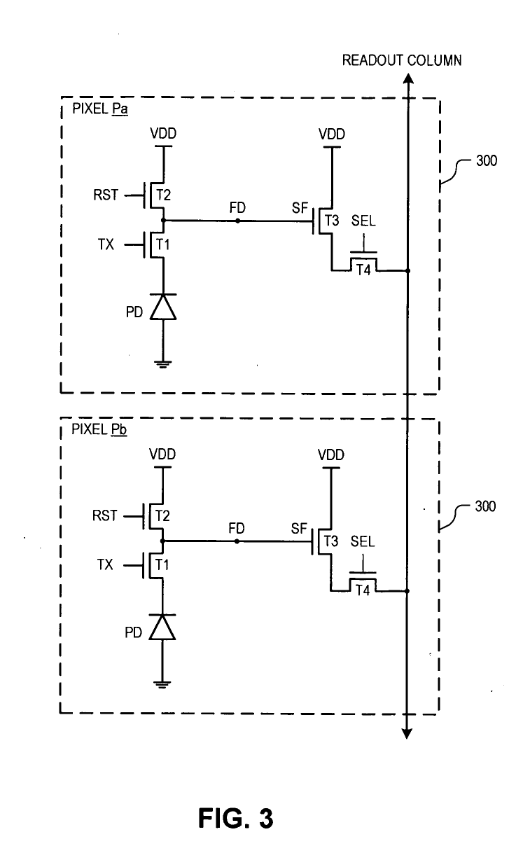

FIG. 3 is a circuit diagram illustrating pixel circuitry 300 of two four-transistor (“4T”) pixels within a BSI imaging array, in accordance with an embodiment of the invention. Pixel circuitry 300 is one possible pixel circuitry architecture for implementing each pixel within pixel array 200 of FIG. 2. However, it should be appreciated that embodiments of the present invention are not limited to 4T pixel architectures; rather, one of ordinary skill in the art having the benefit of the instant disclosure will understand that the present teachings are also applicable to 3T designs, 5T designs, and various other pixel architectures.

In FIG. 3, pixels Pa and Pb are arranged in two rows and one column. The illustrated embodiment of each pixel circuitry 300 includes a photodiode PD, a transfer transistor T1, a reset transistor T2, a source-follower (“SF”) transistor T3, and a select transistor T4. During operation, reset transistor T2 is coupled between a power rail VDD and the floating diffusion node FD to reset FD (e.g., charge the FD to a preset voltage) under control of a reset signal RST. During an image acquisition window, photo-generated charge carriers (e.g., electrons) accumulate within photodiode PD. Subsequently, transfer transistor T1 receives a transfer signal TX, which transfers the charge accumulated in photodiode PD to floating diffusion node FD. In one embodiment, floating diffusion node FD may be coupled to an additional storage capacitor for temporarily storing image charges.

The floating diffusion node FD is coupled to control the gate of SF transistor T3. SF transistor T3 is coupled between the power rail VDD and select transistor T4. SF transistor T3 operates as a source-follower providing a high impedance output from the pixel. Finally, select transistor T4 selectively couples the output of pixel circuitry 300 to the readout column line under control of a select signal SEL. In one embodiment, the TX signal, the RST signal, and the SEL signal are generated by control circuitry 220.

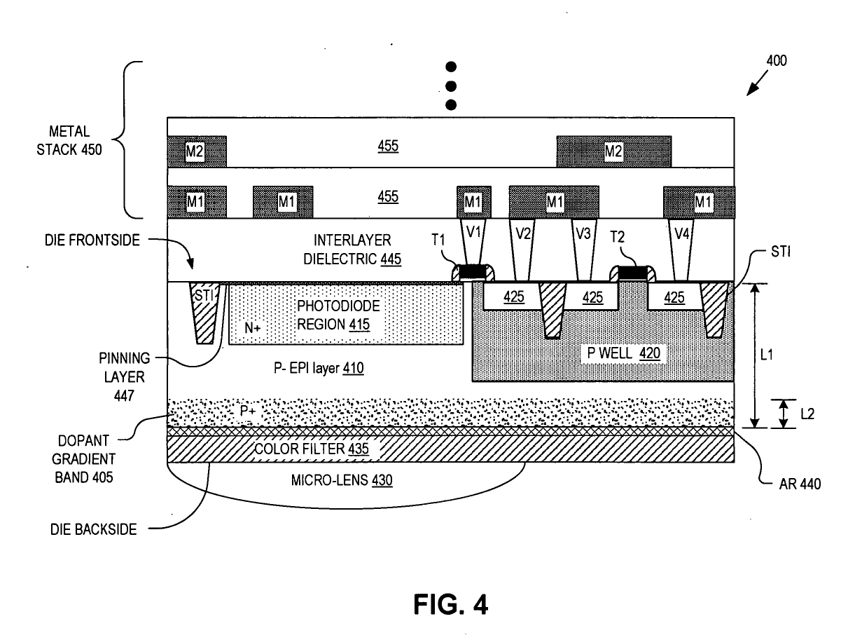

FIG. 4 is a cross sectional view of BSI imaging pixel 400, in accordance with an embodiment of the invention. Imaging pixel 400 is one possible implementation of pixels P1 to Pn within pixel array 205. The illustrated embodiment of imaging pixel 400 includes a P+ dopant gradient band 405, an P− epitaxial (“epi”) layer 410, a photodiode region 415, a P well 420, N+ source/drain diffusions 425, pixel circuitry (only transfer transistor T1 and reset transistor T2 are illustrated), a microlens 430, a color filter layer 435, an antireflective (“AR”) film 440, an inter-metal dielectric layer 445, a P+ passivation or pinning layer 447, and a metal stack 450. The illustrated embodiment of metal stack 450 includes multiple metal layers (e.g., M1, M2, etc.) separated by inter-metal dielectrics 455, and interconnected with vias (e.g., V1, V2, V3, etc.). Although FIG. 4 illustrates only a two layer metal stack, metal stack 450 may include more or less layers for routing signals over the front side of pixel array 205. Finally, shallow trench isolations (“STI”) isolate internal components of imaging pixel 400 and isolate imaging pixel 400 from adjacent pixels (not illustrated). In some embodiments, an additional or alternative AR film may be disposed over the outer surface of microlens 430.

FIG. 4 illustrates BSI imaging pixel 400 formed in a lightly doped P− epi layer 410 initially grown over a highly doped P+ substrate. However, it should be appreciated that the starting materials could also be a lightly doped N− epi layer over a highly doped N+ substrate. Similarly, the starting wafer could also include a silicon-on-insulator (“SOI”) structure. FIG. 4 is merely intended to be representative and is not necessarily drawn to scale.

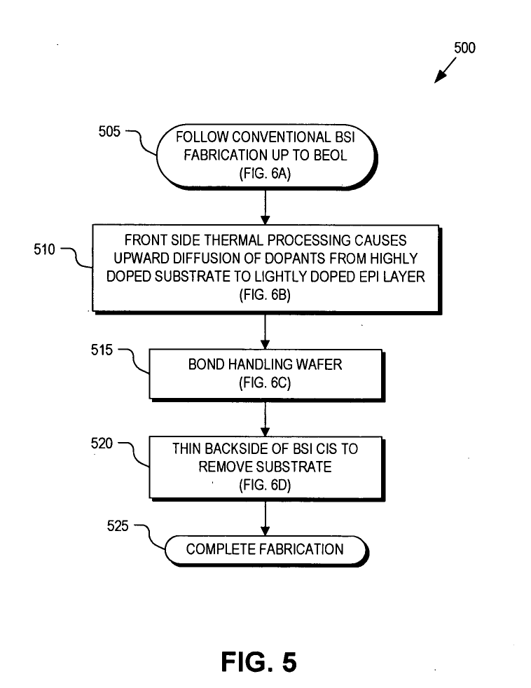

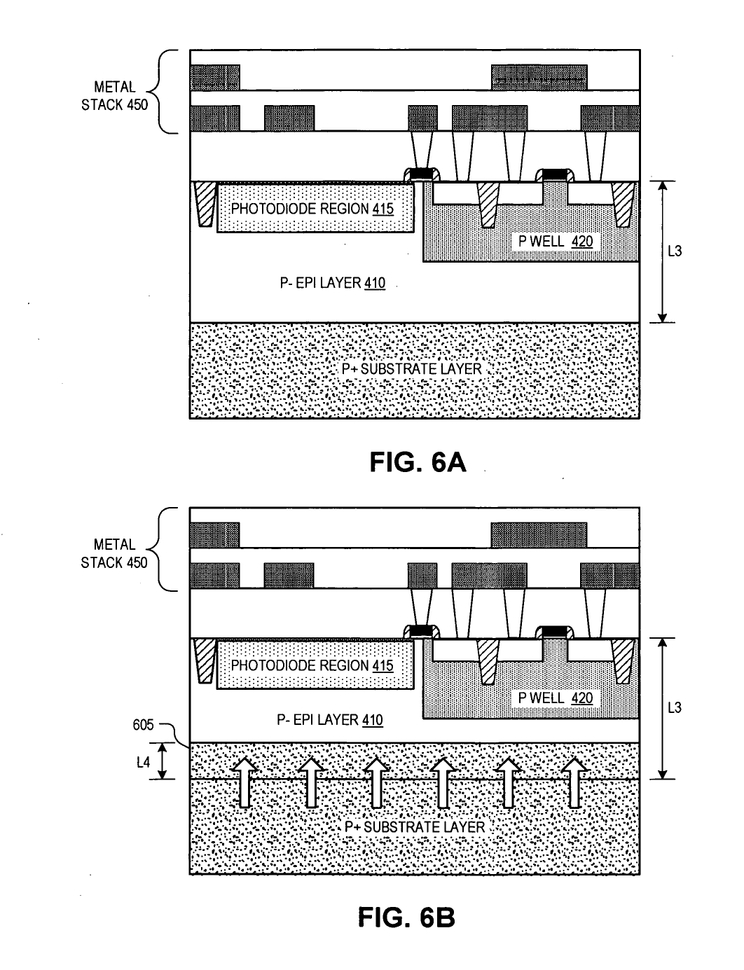

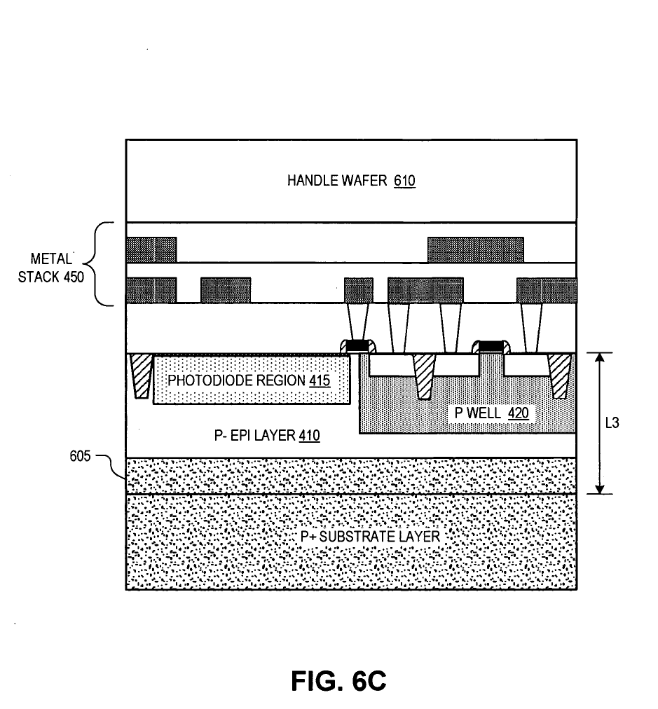

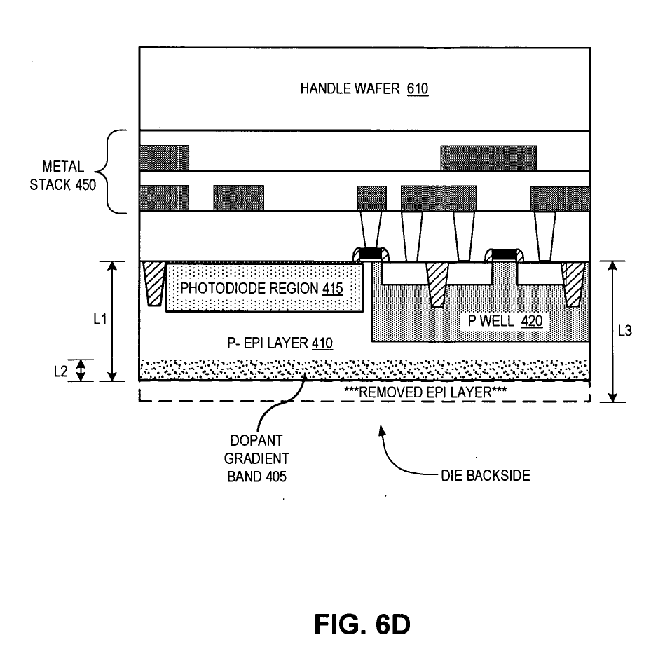

FIG. 5 is a flow chart illustrating a process 500 for fabricating BSI imaging pixel 400, in accordance with an embodiment of the invention. Process 500 is described with reference to FIGS. 6A-6D. The order in which some or all of the process blocks appear in process 500 should not be deemed limiting. Rather, one of ordinary skill in the art having the benefit of the present disclosure will understand that some of the process blocks may be executed in a variety of orders not illustrated. The below fabrication process illustrates the formation of dopant gradient band 405 in the context of a specific BSI process flow; however, it should be appreciated that dopant gradient band 405 may be used in any number of BSI process flows to cure backside surface defects and promote upward migration and efficient collection of photogenerated charge carriers during BSI operation.

In a process block 505, fabrication of imaging pixel 400 follows conventional techniques right up to fabrication of the back-end-of-the-line (“BEOL”) components including diffusion implants, silicides, pixel transistor circuitry, and metal stack 450 (see FIG. 6A). As illustrated, the starting materials upon which imaging pixel 400 is built, typically is a highly doped substrate layer over which a lower doped epitaxial layer (e.g., epi layer 410) has been grown. During the thermal processing of front side components, the dopants of the highly doped substrate layer will have migrated upward from the backside towards the frontside (process block 510; illustrated FIG. 6B). Some of the significant thermal processing steps that cause this dopant diffusion include the growth of epi layer 410 itself and the high temperature well implants of P wells 420; however, other frontside fabrication processes also contribute to the dopant migration. In one embodiment, the front side processing thermal budget results in a diffusion tail 605 extending 1 μm (e.g., L4=1 μm) into epi layer 410 from the substrate layer.

The fabrication technique described herein exploits the natural upward diffusion profile of the dopants resulting from fabrication of epi layer 410 and front side CMOS circuit processing. The front side thermal processing ensures that the migrated dopants are annealed and evenly activated, leaving little or no unactivated regions when compared to a separate backside dopant implant and anneal process. Exploiting the natural upward diffusion profile of the dopants from the substrate layer also eliminates the backside dopant implant and anneal processes, reducing the overall fabrication cost and time.

In a process block 515 (FIG. 6C), a handle wafer 605 is bonded to the front side of the die including the partially fabricated imaging pixel 400. Handle wafer 605 is used as a handle to hold the partially fabricated imaging pixel 400 while thinning its backside.

In a process block 520 (FIG. 6D), the backside of the array of imaging sensors is thinned to remove the P+ substrate layer and expose P− epi layer 410. Backside thinning may be performed with a combination of chemical mechanical polishing (“CMP”) and/or chemical etching. In one embodiment, the substrate layer and the epi layer 410 are thinned until the substrate layer is entirely removed and the remaining thickness L1 of epi layer 410 is less than 4.0 μm and a portion of diffusion tail 605 remains along the bottom side of epi layer 410 as dopant gradient band 405. In some embodiments, the target thickness L1 is between 1.5 μm and 3.0 μm. In one particular embodiment, the target thickness L1 is approximately 2.3 μm, while the thickness L2 of dopant gradient band 405 is approximately 0.5-0.8 μm. Of course, other target thickness for L1 and L2 are possible as well.

The typical thermal budget for the epi layer growth and front side CMOS processing causes diffusion tail 605 to grow 1.5 to 2.0 μm into epi layer 410. Conventional image sensor fabrication techniques start with an initial epi layer thickness L3 of approximately 5 μm or greater to provide adequate sacrificial space within the bottom portion of epi layer 410 for diffusion tail 605 to be completely removed. Embodiments of the technique disclosed herein may start with an initial epi layer thickness L3 of approximately 3-5 μm (in one embodiment L3 is selected to be 4 μm). In these embodiments, epi layer 410 is thinned to a target thickness L1 of approximately 2.0-2.3 μm for epi layer 410 and a target thickness L2 of approximately 0.5-0.8 μm for dopant gradient band 405. Accordingly, the initial thickness L3 of epi layer 410 is selected such that diffusion tail 605 migrates upward to within 3.0 μm or less of the top surface of epi layer 410, and in the illustrated embodiment to within 2.0 μm of the top surface of epi layer 410.

After backside thinning, fabrication of imaging pixel 400 may be completed with the addition of one or more other passivation layers (not illustrated), AR film 440, color filter 435, and microlens 430 (process block 525). Handling wafer 605 is also removed. It should be appreciated that other conventional layers (not illustrated) may also be added and/or some illustrated material layers may not be used.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

1. A method of fabricating an image sensor, comprising:
fabricating front side components of the image sensor into or onto a first side of an epitaxial layer disposed over a substrate layer;
diffusing dopants from the substrate layer through a second side of the epitaxial layer to create a dopant gradient band in the epitaxial layer adjacent to the substrate layer, wherein the diffusing of the dopants to create the dopant gradient band in the epitaxial layer occurs after or during fabricating the front side components into or onto the first side of the epitaxial layer; and
thinning a backside of the image sensor to remove the substrate while retaining at least a portion of the dopant gradient band in the epitaxial layer.

2. The method of claim 1, wherein the dopants are diffused into the epitaxial layer and annealed within the epitaxial layer during thermal processing of the front side components.

3. The method of claim 2, wherein an initial thickness of the epitaxial layer prior to thinning the backside is selected such that the dopants from the substrate layer diffuse to within less than 3.0 μm of the first side of the epitaxial layer.

4. The method of claim 2, wherein thinning the backside of the image sensor includes thinning the epitaxial layer from the second side without removing all of the dopant gradient band.

5. The method of claim 4, further comprising bonding a handling wafer to a front side of the image sensor after fabricating the front side components and prior to thinning the backside.

6. The method of claim 5, wherein thinning the epitaxial layer comprises applying a chemical mechanical polish (“CMP”) to the backside of the image sensor until the dopant gradient band is thinned to a desired thickness.

7. The method of claim 4, wherein the epitaxial layer is thinned to between 1.5 and 3.0 μm thick.

8. The method of claim 7, wherein the epitaxial layer is thinned until the dopant gradient band is approximately 0.5-0.8 μm thick and the epitaxial layer is approximately 2.0-2.3 μm thick.

9. The method of claim 8, wherein the dopants from the substrate layer are diffused approximately 2.0 μm into the epitaxial layer prior to thinning the backside of the array.

10. The method of claim 1, wherein the substrate layer comprises a P+ highly doped substrate layer and the epitaxial layer outside of the dopant gradient band comprises a P− lower doped epitaxial layer.

11. A method of fabricating an array of backside illuminated (“BSI”) complementary metal-oxide semiconductor (“CMOS”) image sensors (“CIS”), comprising:
fabricating front side components of the BSI CIS into or onto a first side of an epitaxial layer disposed over a substrate layer;
diffusing dopants from the substrate through a second side of the epitaxial layer to create a dopant gradient band in the epitaxial layer adjacent to the substrate layer, wherein the diffusing of the dopants to create the dopant gradient band in the epitaxial layer occurs after or during fabricating the front side components into or onto the first side of the epitaxial layer; and
thinning a backside of the array to remove the substrate layer while retaining at least a portion of the dopant gradient band in the epitaxial layer.

12. The method of claim 11, wherein the dopants are diffused into the epitaxial layer and annealed within the epitaxial layer during thermal processing of the front side components.

13. The method of claim 12, wherein thinning the backside of the array includes thinning the epitaxial layer from the second side without removing all of the dopant gradient band.

14. The method of claim 13, further comprising bonding a handling wafer to a front side of the array after fabricating the front side components and prior to thinning the backside of the array.

15. The method of claim 14, wherein thinning the epitaxial layer comprises applying a chemical mechanical polish (“CMP”) to the backside of the array until the dopant gradient band is thinned to a desired thickness.

16. The method of claim 13, wherein the epitaxial layer is thinned to between 1.5 and 3.0 μm thick.

17. The method of claim 16, wherein the epitaxial layer is thinned until the dopant gradient band is approximately 0.5-0.8 μm thick and the epitaxial layer is approximately 2.0-2.3 m thick.

18. The method of claim 17, wherein the dopants from the substrate layer are diffused approximately 2.0 μm into the epitaxial layer prior to thinning the backside of the array.

19. The method of claim 11, wherein the substrate layer comprises a P+ highly doped substrate layer and the epitaxial layer outside of the dopant gradient band comprises a P− lower doped epitaxial layer.

20. The method of claim 11, wherein fabricating the front side components comprises:
forming photodiode regions and associated pixel circuitry on or within the front side of an epitaxial layer; and
forming a metal stack over the front side of the epitaxial layer for routing electrical signals over the front side, wherein the photodiode regions are illuminated from the backside of the array during operation of the BSI CIS.

21. The method of claim 20, further comprising forming an array of microlens over the backside of the array to focus light into the photodiode regions.

22. The method of claim 1, wherein the diffusing of the dopants to create the dopant gradient band in the epitaxial layer occurs during thermal processing of the front side components thereby exploiting existing high temperature fabrication steps to perform the diffusing without adding an additional annealing process specifically for creating the dopant gradient band.
